(19) United States
(12) Patent Application Publication
(10) Pub. No.: US 2015/0171291 A1
(43) Pub. Date: Jun. 18, 2015

(54) LIGHT EMITTING DEVICE AND MANUFACTURING METHOD FOR WAVELENGTH CONVERSION LAYER

(71) Applicant: Genesis Photonics Inc., Tainan City (TW)

(72) Inventors: Kuan-Chieh Huang, Tainan City (TW); Yi-Fan Li, Tainan City (TW)

(21) Appl. No.: 14/571,312

(22) Filed: Dec. 16, 2014

(30) Foreign Application Priority Data
Dec. 16, 2013 (TW) 102146466
Dec. 16, 2013 (TW) 102146471
Dec. 15, 2014 (TW) 103143733

(51) Int. Cl. H01L 33/56; H01L 33/48; H01L 33/54; H01L 33/50

(52) U.S. Cl. CPC H01L 33/56; H01L 33/507; H01L 33/483; H01L 33/54

(57) ABSTRACT

The disclosure provides a light emitting device, and a manufacturing method for a wavelength conversion layer. The light emitting device includes a support, a light emitting diode, and a material layer. The light emitting diode is arranged on the support and coupled to the support. A light emission peak wavelength of the light emitting diode is between 250 nm and 470 nm. The material layer is configured to cover the light emitting diode, wherein the material layer comprises a poly(vinylidene fluoride-hexafluoropropylene) copolymer.

### BACKGROUND OF THE INVENTION

1. Field of the Invention

The present invention relates to a light emitting device, and more particularly, to a light emitting device utilizing a poly(vinylidene fluoride-hexafluoropropylene) copolymer as a package material.

2. Description of the Prior Art

Since light emitting diodes (LEDs) have advantages of long life, compact size and low power consumption, the light emitting diodes are widely used in various illumination devices and display devices. A conventional light emitting diode package structure is formed by utilizing an epoxy resin to cover the light emitting diode, and then curing the resin. However, the epoxy resin is not resistant to ultraviolet light, and the epoxy resin may have yellowing aging phenomenon when exposed to ultraviolet radiation for a long time, so that the light extraction efficiency and light color of the light emitting diode are further affected. Moreover, the epoxy resin cannot withstand high temperature, thus the epoxy resin is not suitable to package a high power light emitting diode chip.

### SUMMARY OF THE INVENTION

The disclosure is to provide a light emitting device utilizing a poly(vinylidene fluoride-hexafluoropropylene) copolymer as a package material and a manufacturing method for wavelength conversion layer.

According to an embodiment of the disclosure, a light emitting device of the disclosure comprises a support; a light emitting diode, arranged on the support, and coupled to the support, wherein a light emission peak wavelength of the light emitting diode is between 250 nm and 470 nm; and a material layer, covering the light emitting diode, wherein the material layer comprises a poly(vinylidene fluoride-hexafluoropropylene) copolymer.

According to an embodiment of the disclosure, a light emitting device of the disclosure comprises a support; an ultraviolet light emitting diode, arranged on the support, and coupled to the support; and a material layer, covering the light emitting diode, wherein the material layer comprises a poly(vinylidene fluoride-hexafluoropropylene) copolymer.

According to an embodiment of the disclosure, a light emitting device of the disclosure comprises a support; a light emitting diode, arranged on the support, and coupled to the support; a material layer, covering the light emitting diode, wherein the material layer comprises a poly(vinylidene fluoride-hexafluoropropylene) copolymer; and a phosphor layer, arranged on the light emitting diode for converting a wavelength of light emitted from the light emitting diode.

A manufacturing method for wavelength conversion layer of the disclosure is applicable to a light emitting device, the manufacturing method comprises dissolving a material comprising a poly(vinylidene fluoride-hexafluoropropylene) copolymer in an organic solvent to form a solution; applying the solution on a substrate; performing a baking process to form a material layer by the solution applied on the substrate; and forming a phosphor layer on the material layer.

In contrast to the prior art, the light emitting device of the disclosure utilizes the poly(vinylidene fluoride-hexafluoropropylene) copolymer to form a material layer in order to package a light emitting diode. Since the poly(vinylidene fluoride-hexafluoropropylene) copolymer is resistant to ultraviolet light and high temperature, the light emitting device of the disclosure can prevent yellowing aging phenomenon due to being exposed to ultraviolet radiation for a long time, and is applicable to package of high power light emitting diodes.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

FIG. 1 is a diagram showing a light emitting device according to a first embodiment of the disclosure.

FIG. 2 is a diagram showing a light emitting device according to a second embodiment of the disclosure.

FIG. 3 is a diagram showing a light emitting device according to a third embodiment of the disclosure.

FIG. 4 is a diagram showing a light emitting device according to a fourth embodiment of the disclosure.

FIG. 5 is a diagram showing a light emitting device according to a fifth embodiment of the disclosure.

FIG. 6 is a diagram showing a light emitting device according to a sixth embodiment of the disclosure.

FIG. 7 is a diagram showing a light emitting device according to a seventh embodiment of the disclosure.

FIG. 8 is a diagram showing a light emitting device according to an eighth embodiment of the disclosure.

FIG. 9 is a diagram showing a light emitting device according to a ninth embodiment of the disclosure.

FIG. 10 is a diagram showing a light emitting device according to a tenth embodiment of the disclosure.

FIG. 11 is a diagram showing a light emitting device according to an eleventh embodiment of the disclosure.

FIG. 12 is a diagram illustrating a manufacturing method for a wavelength conversion layer of the disclosure.

### DETAILED DESCRIPTION

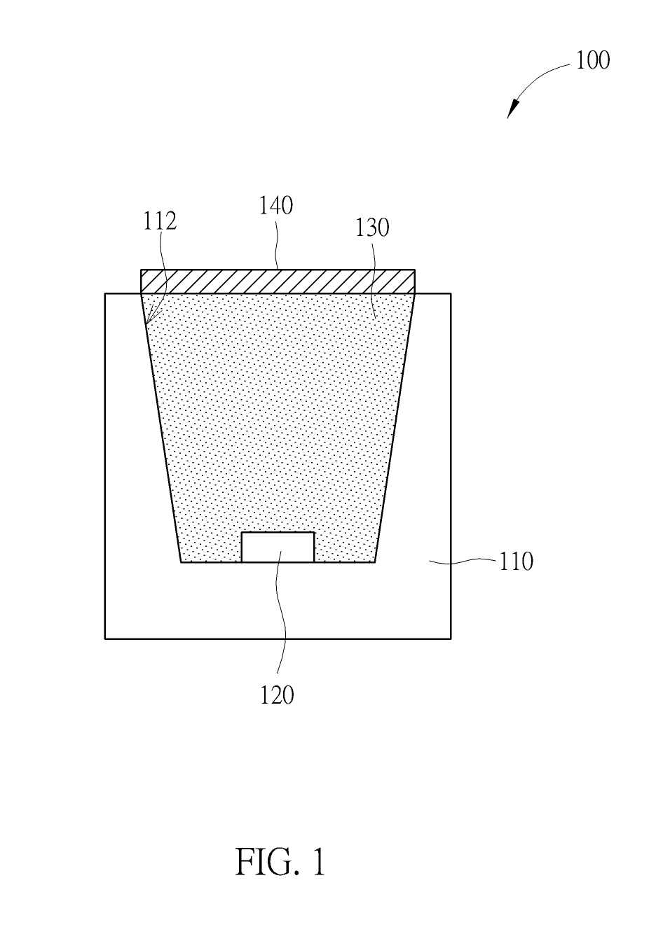

Please refer to FIG. 1. FIG. 1 is a diagram showing a light emitting device according to a first embodiment of the disclosure. As shown in FIG. 1, the light emitting device 100 of the disclosure comprises a support 110, a light emitting diode 120, and a material layer 130. The support 110 has a recess 112. The light emitting diode 120 is arranged in the recess 112, and is coupled to the support 110. The material layer 130 is filled into the recess 112 for covering the light emitting diode 120. The material layer 130 comprises a poly(vinylidene fluoride-hexafluoropropylene) copolymer, which is represented by a chemical formula:

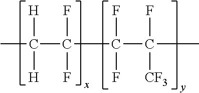

A molecular weight of the poly(vinylidene fluoride-hexafluoropropylene) copolymer is between 390000 g/mole and 460000 g/mole. In an embodiment, when x and y (x and y are positive integers) satisfy a condition of 390000<64x+150y<460000, the poly(vinylidene fluoride-hexafluoropropylene) copolymer is resistant to a higher temperature, and light transmittance of the poly(vinylidene fluoride-hexafluoropropylene) copolymer is higher than 80%. In an embodiment of the disclosure, the molecular weight of the poly(vinylidene fluoride-hexafluoropropylene) copolymer of the material layer 130 is 400000 g/mole or 455000 g/mole.

According to the aforementioned arrangement, since the material layer 130 is resistant to ultraviolet light, the light emitting diode 120 of the light emitting device of the disclosure can be an ultraviolet light emitting diode, and a peak wavelength of light emitted by the ultraviolet light emitting diode is between 250 nm and 410 nm. For example, a light emission peak wavelength of the light emitting diode 120 can be 2365 nm, 385 nm or 405 nm. In addition, in other embodiments of the disclosure, the light emitting diode 120 can be a blue light emitting diode, and a peak wavelength of light emitted by the blue light emitting diode is between 410 nm and 470 nm. But the light emitting diode 120 of the disclosure is not limited to the previous embodiment, the peak wavelength of light emitted by the light emitting diode 120 of the disclosure can locate within other ranges. Moreover, the material layer 130 can withstand up to 450 degrees Celsius. Compared to the epoxy resin which can only withstand up to 200 degrees Celsius, the material layer 130 has better reliability. Therefore, the light emitting diode 120 of the light emitting device 100 of the disclosure can be a high power light emitting diode.

In addition, the light emitting device 100 can further comprise a phosphor layer 140 arranged on the material layer 130, for converting the wavelength of light emitted from the light emitted diode 120, wherein a light emission peak wavelength of the phosphor layer 140 is longer than the peak wavelength of light emitted by the light emitting diode 120. For example, the phosphor layer 140 can convert ultraviolet light or blue light emitted from the light emitting diode 120 into yellow light or red light, and the yellow light or red light can be mixed with the light emitted from the light emitting diode 120. An orthographic projection area of the phosphor layer 140 on the support 10 is greater than or equal to an orthographic projection area of the material layer 130 on the support 110, such that light conversion efficiency of the phosphor layer 140 and light uniformity of the light emitting device 100 can be improved.

On the other hand, in embodiments of the disclosure, the light emitting device 100 is not limited to comprising only one phosphor layer. The light emitting device 100 can also comprise at least two phosphor layers, which are arranged on the material layer 130, having different light emission peak wavelengths. In addition, the phosphor layer having a shorter light emission peak wavelength is arranged relatively close to the light emitting diode 120, and the phosphor layer having a longer light emission peak wavelength is arranged relatively far from the light emitting diode 120, such that better phosphor conversion efficiency can be achieved, and color saturation of the light emitting device 100 is improved.

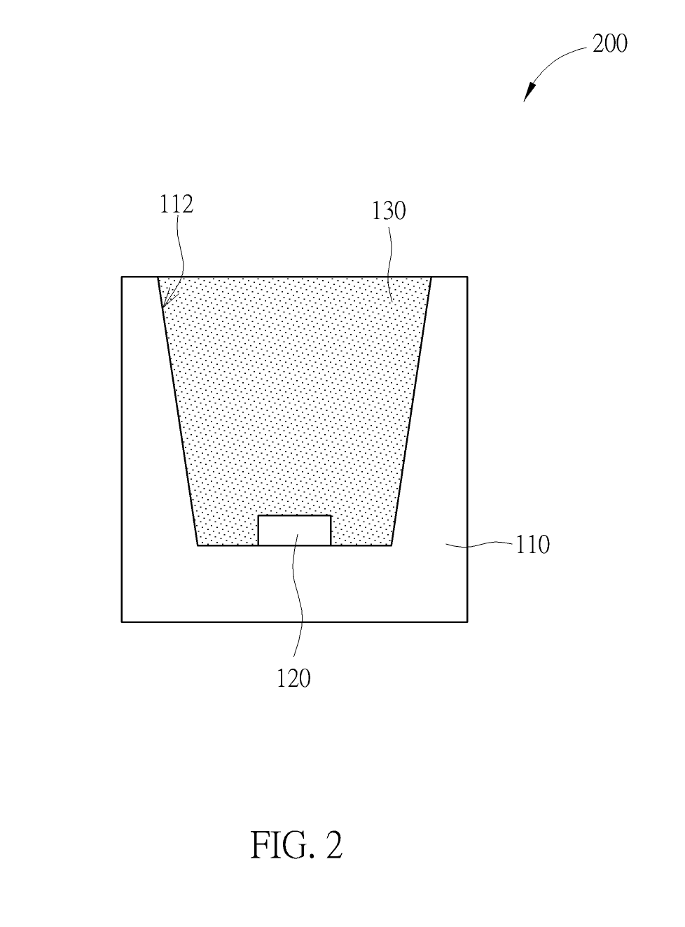

Please refer to FIG. 2, and refer to FIG. 1 as well. FIG. 2 is a diagram showing a light emitting device according to a second embodiment of the disclosure. As shown in FIG. 2, the support 110, the light emitting diode 120 and the material layer 130 of the light emitting device 200 are identical to those shown in FIG. 1. Different from the embodiment of FIG. 1, the light emitting device 200 of the disclosure does not comprise a phosphor layer. The light emitting device 200 of the disclosure can select a proper light emitting diode according to design requirement, and utilize the light emitting diode 120 to directly emit light without wavelength conversion.

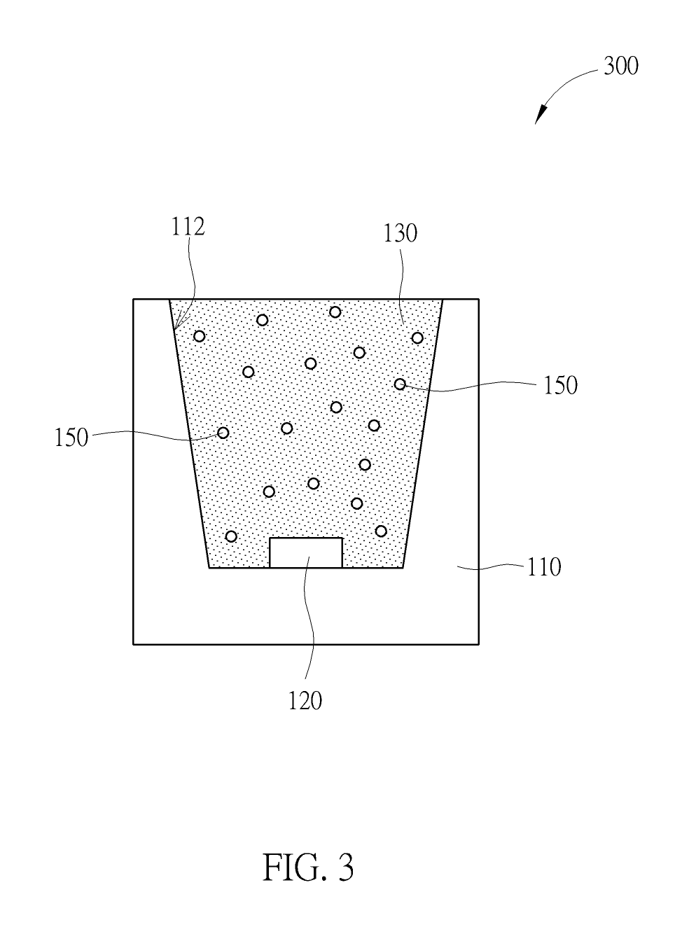

Please refer to FIG. 3, and refer to FIG. 1 as well. FIG. 3 is a diagram showing a light emitting device according to a third embodiment of the disclosure. As shown in FIG. 3, the support 110, the light emitting diode 120 and the material layer 130 of the light emitting device 300 are identical to those shown in FIG. 1. Different from the embodiment of FIG. 1, the light emitting device 300 of the disclosure does not comprise a phosphor layer. Oppositely, the light emitting device 300 of the disclosure further comprises phosphor 150 distributed in the material layer 130, for converting the wavelength of light emitted from the light emitting diode 120. A primary size of the phosphor body 150 is between 5 micrometers and 30 micrometers, and a light emission peak wavelength of the phosphor 150 is longer than the peak wavelength of light emitted by the light emitting diode 120. In addition, a difference between an absorption peak wavelength of the phosphor 150 and the peak wavelength of light emitted by the light emitting diode 120 is shorter than 150 nm, such that better phosphor conversion efficiency can be achieved. In addition, the material layer 130 can comprise at least two kinds of phosphor having different light emission peak wavelengths, such that the light emitted from the light emitting diode 120 can be converted into two different color light, so as to increase color saturation of the light emitting device 300.

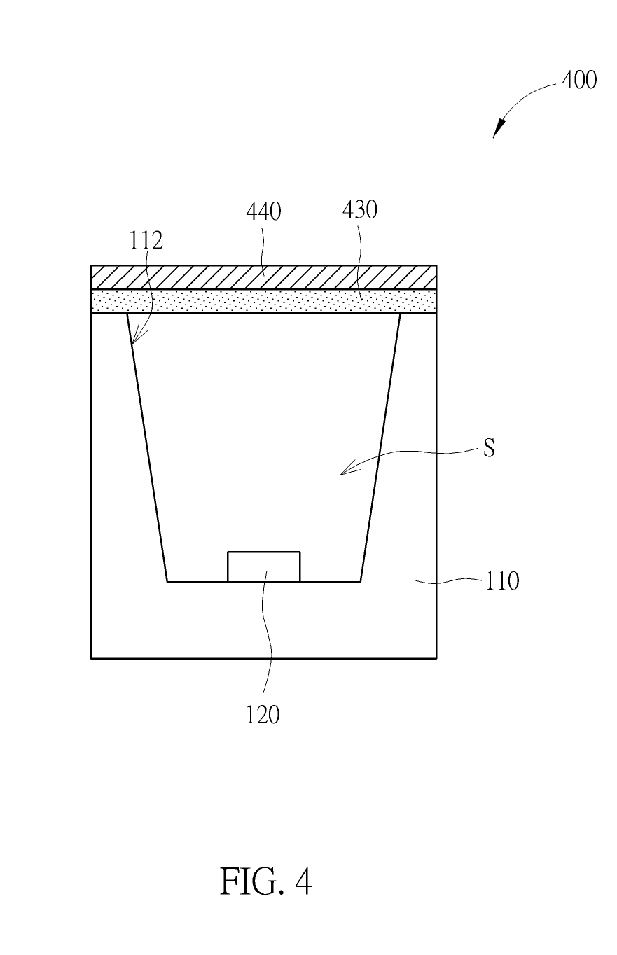

Please refer to FIG. 4. FIG. 4 is a diagram showing a light emitting device according to a fourth embodiment of the disclosure. As shown in FIG. 4, the light emitting device 400 of the disclosure comprises a support 110, a light emitting diode 120 and a material layer 430 comprising a film made of the poly(vinylidene fluoride-hexafluoropropylene) copolymer. The support 110 has a recess 112. The light emitting diode 120 is arranged in the recess 112, and is coupled to the support 110. The material layer 430 is arranged on the light emitting diode 120, and an accommodation space S is formed between the material layer 430 and the recess 112. The accommodation space S can be in a vacuum state, or the accommodation space S can be filled with an inert gas (such as nitrogen) or other low reactivity gases. In the embodiment of the disclosure, the material layer 430 covers an opening of the recess 112, and a thickness of the material layer 430 is smaller than a thickness of the light emitting diode 120, such that the material layer 430 can have better light transmittance. The thickness of the material layer 430 is not greater than 100 micrometers.

In addition, the light emitting device 400 can further comprise a phosphor layer 440 arranged on the material layer 430, for converting the wavelength of light emitted from the light emitted diode 120. An orthographic projection area of the phosphor layer 440 on the support 110 is greater than or equal to an orthographic projection area of the material layer 430 on the support 110, such that light conversion efficiency of the phosphor layer 440 and light uniformity of the light emitting device 400 can be improved. On the other hand, in embodiments of the disclosure, the light emitting device 400 is not limited to comprising only one phosphor layer. The light emitting device 400 can also comprise at least two phosphor layers, which are arranged on the material layer 430, having different light emission peak wavelengths. The phosphor layer having a shorter light emission peak wavelength is arranged relatively close to the light emitting diode 120, and the phosphor layer having a longer light emission peak wavelength is arranged relatively far from the light emitting diode 120, such that better phosphor conversion efficiency can be achieved, and color saturation of the light emitting device 400 is improved.

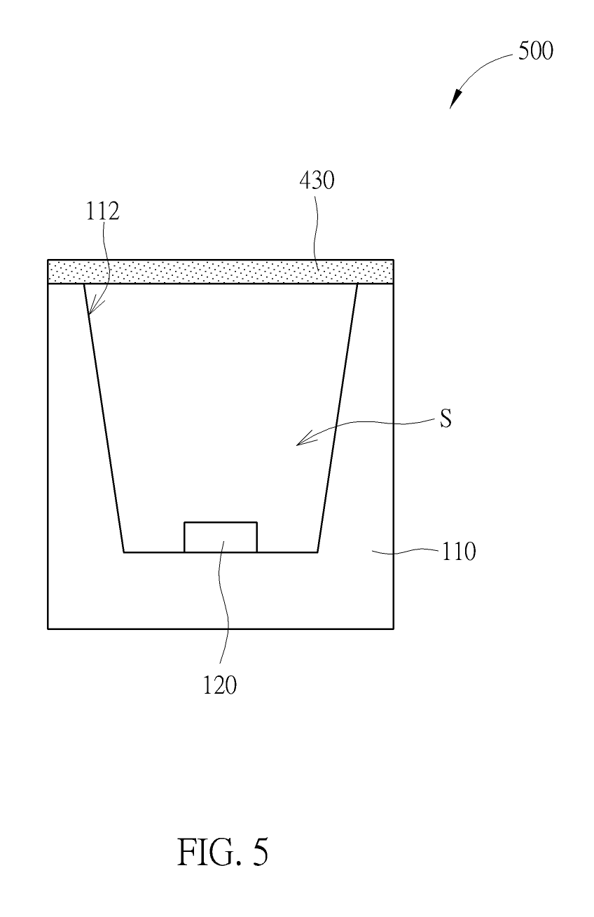

Please refer to FIG. 5, and refer to FIG. 4 as well. FIG. 5 is a diagram showing a light emitting device according to a fifth embodiment of the disclosure. As shown in FIG. 5, the support 110, the light emitting diode 120 and the material layer 430 of the light emitting device 500 are identical to those shown in FIG. 4. Different from the embodiment of FIG. 4, the light emitting device 500 of the disclosure does not comprise a phosphor layer. The light emitting device 500 of the disclosure can select a proper light emitting diode 120 according to design requirement, and utilize the light emitting diode 120 to directly emit light without wavelength conversion.

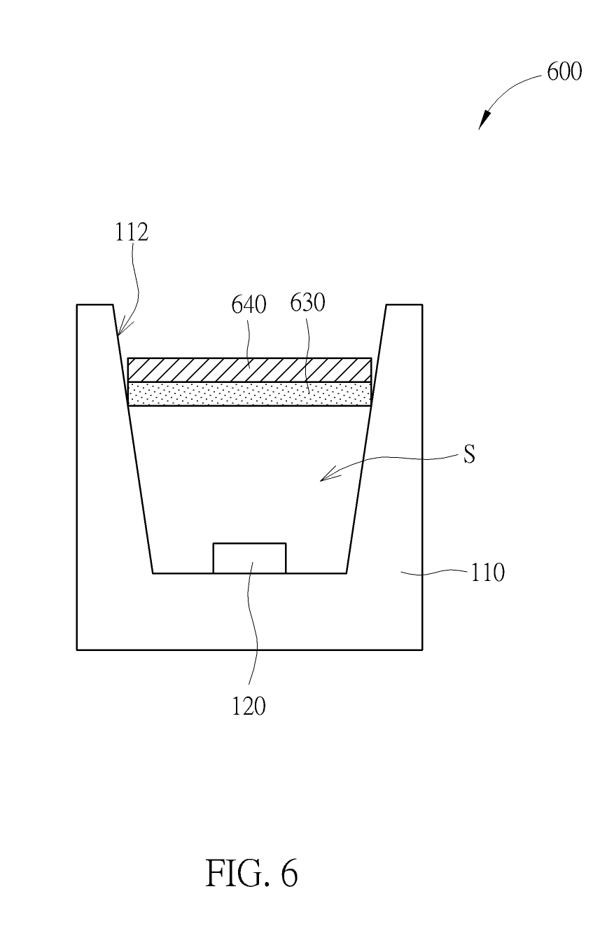

Please refer to FIG. 6, and refer to FIG. 4 as well. FIG. 6 is a diagram showing a light emitting device according to a sixth embodiment of the disclosure. As shown in FIG. 6, the support 110 and the light emitting diode 120 of the light emitting device 600 are identical to those shown in FIG. 4. Different from the embodiment of FIG. 4, the material layer 630 of the disclosure is fixed within the recess 112, and the light emitting device 600 further comprise a phosphor layer 640 arranged on the material layer 630, so as to effectively utilize the phosphor layer 640 and the material layer 630, in order to arrange the phosphor layer 640 and the material layer 630 on all light emission paths of the light emitted from the light emitting diode 120, for cost reduction.

It should be noted that the accommodation space S in FIG. 4 to FIG. 6 is not limited to be in a vacuum state or filled with gas. The accommodation space S can also arranged with transparent supporting element for supporting the material layer. A refractive index of the transparent supporting element is between a refractive index of the light emitting diode and a refractive index of the poly(vinylidene fluoride-hexafluoropropylene) copolymer, such that light extraction of the light emitting device can be improved. The transparent supporting element has volume close to that of the accommodation space S.

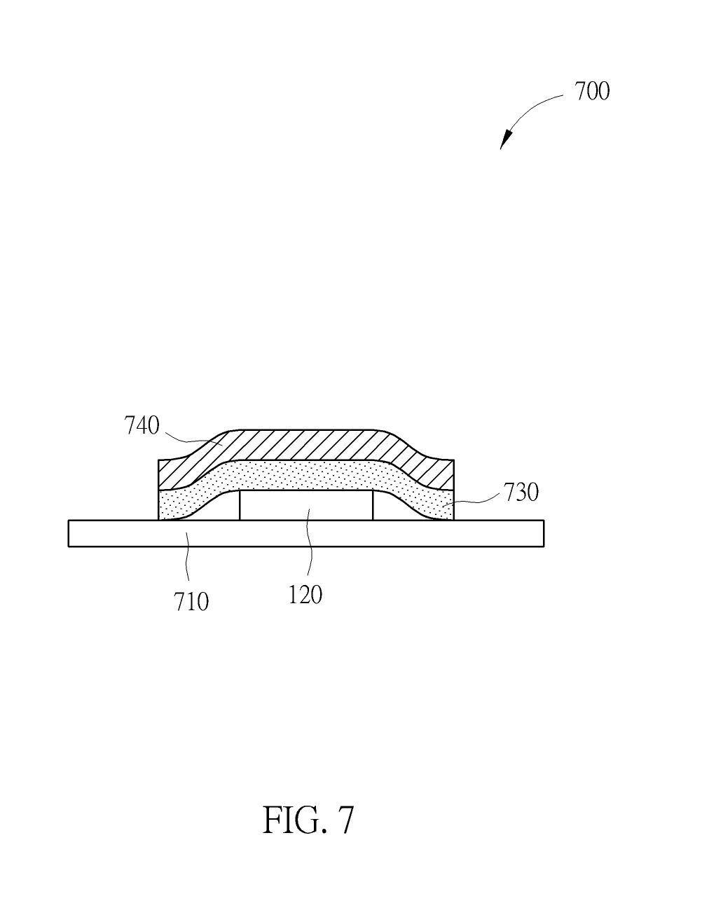

Please refer to FIG. 7. FIG. 7 is a diagram showing a light emitting device according to a seventh embodiment of the disclosure. As shown in FIG. 7, the light emitting device 700 of the disclosure comprises a support 710, a light emitting diode 120 and a material layer 730 comprising a film made of the poly(vinylidene fluoride-hexafluoropropylene) copolymer. The support 710 can be a circuit board. The light emitting diode 120 is arranged on the support 710, and is coupled to the support 710. The material layer 730 is configured to cover the light emitting diode 120, for forming a package structure. The light emitting device 700 can further comprise one (or a plurality of) phosphor layer 740, which is arranged on the material layer 730, similar to those in the aforementioned embodiments, in order to convert wavelength of the light emitted from the light emitting diode 120. An orthographic projection area of the phosphor layer 740 on the support 710 is greater than or equal to an orthographic projection area of the material layer 730 on the support 710. The light emitting diode 120 can be a flip chip light emitting diode, which is coupled to the support 710 by eutectic bonding. In addition, an adhesive layer can be arranged between the material layer 730 and the light emitting diode 120 for strengthening connection between the material layer 730 and the light emitting diode 120, so as to increase reliability of the light emitting device 700.

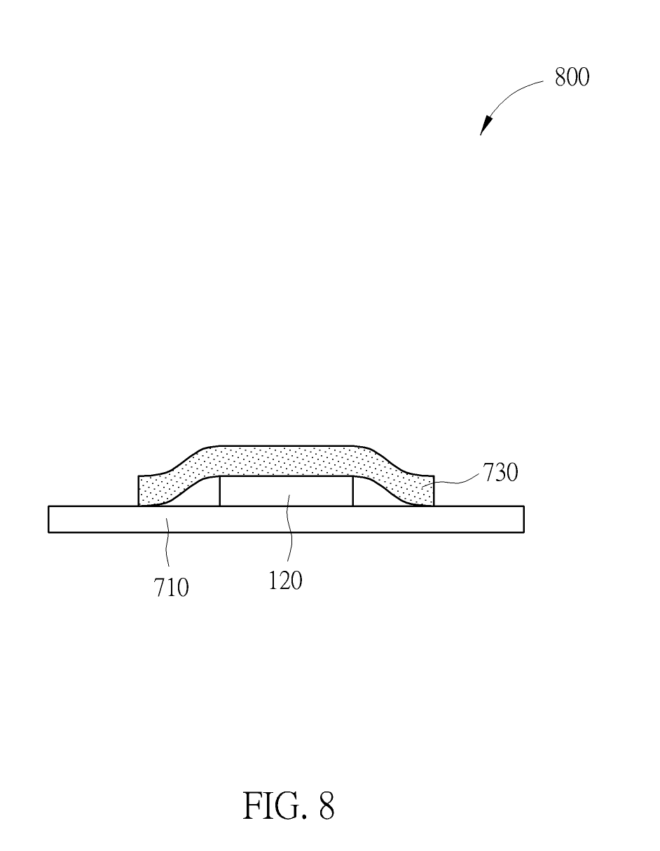

Please refer to FIG. 8, and refer to FIG. 7 as well. FIG. 8 is a diagram showing a light emitting device according to an eighth embodiment of the disclosure. As shown in FIG. 8, the support 710, the light emitting diode 120 and the material layer 730 of the light emitting device 800 are identical to those shown in FIG. 7. Different from the embodiment of FIG. 7, the light emitting device 800 of the disclosure does not comprise a phosphor layer. The light emitting device 800 of the disclosure can select a proper light emitting diode 120 according to design requirement, and utilize the light emitting diode 120 to directly emit light without wavelength conversion.

In the previous embodiments, since the material layer can be formed as a film having a large area, it only needs one cycle of manufacturing time to produce the material layers for packaging multiple light emitting devices, so as to facilitate assembly and reduce package volume and manufacturing cost. Moreover, since the film is relatively thin, the material layer has better light transmittance, such that light extraction of the light emitting device is improved. In addition, since the film type material layer is flexible, a contact surface of the light emitting diode, which contacts the film type material layer, is not necessary to be a plane. The contact surface can include a curved surface or irregular surfaces.

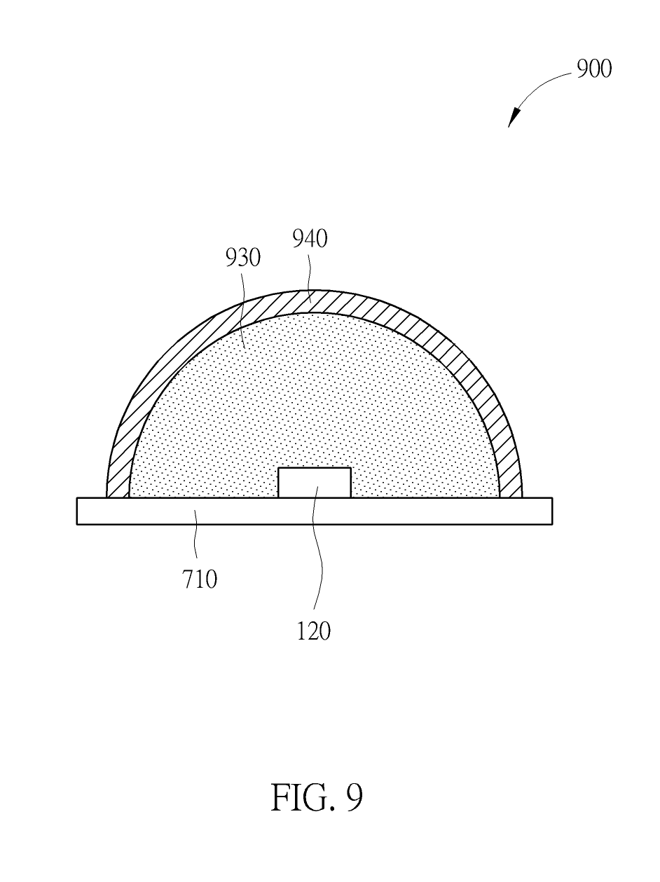

Please refer to FIG. 9. FIG. 9 is a diagram showing a light emitting device according to a ninth embodiment of the disclosure. As shown in FIG. 9, the light emitting device 900 of the disclosure comprises a support 710, a light emitting diode 120 and a material layer 930 formed by the poly(vinylidene fluoride-hexafluoropropylene) copolymer. The support 710 can be a circuit board. The light emitting diode 120 is arranged on the support 710, and is coupled to the support 710. The material layer 930 is arranged on the support 710 and covers the light emitting diode 120, for forming a package structure. The material layer 930 can have an arc surface for increasing light extraction, or the material layer 930 can have a shape arranged according to light emission pattern of the light emitting diode 120. The shape of the material layer 930 is not limited to those shown in the disclosure.

The light emitting device 900 can further comprise a phosphor layer 940 arranged on the material layer 930, for converting the wavelength of light emitted from the light emitted diode 120. An orthographic projection area of the phosphor layer 940 on the support 710 is greater than or equal to an orthographic projection area of the material layer 930 on the support 710, such that light conversion efficiency of the phosphor layer 940 and light uniformity of the light emitting device 900 can be improved. On the other hand, in embodiments of the disclosure, the light emitting device 900 is not limited to comprising only one phosphor layer. The light emitting device 900 can also comprise at least two phosphor layers, which are arranged on the material layer 930, having different light emission peak wavelengths. In addition, the phosphor layer having a shorter light emission peak wavelength is arranged relatively close to the light emitting diode 120, and the phosphor layer having a longer light emission peak wavelength is arranged relatively far from the light emitting diode 120, such that better phosphor conversion efficiency can be achieved, and color saturation of the light emitting device 900 is improved.

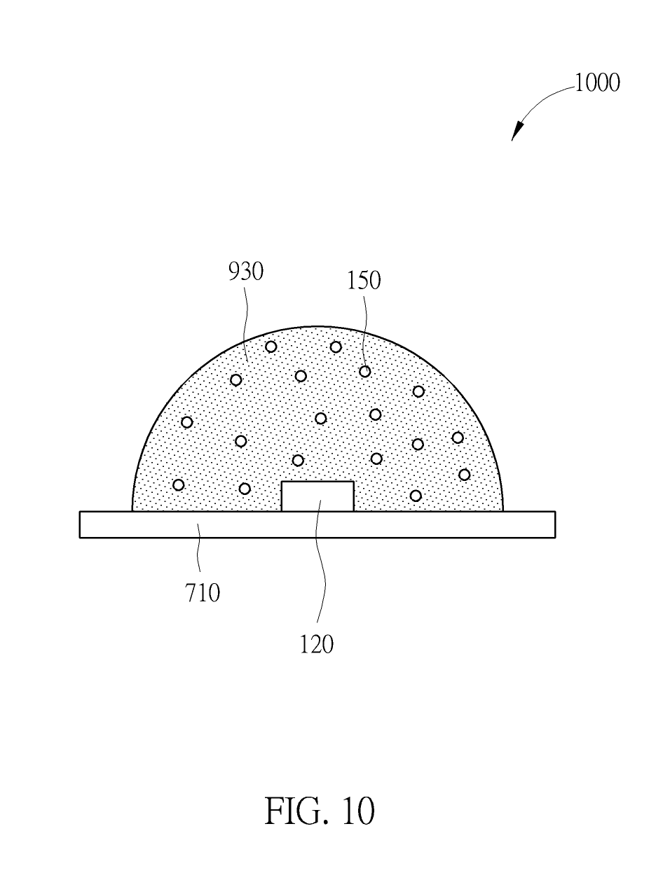

Please refer to FIG. 10, and refer to FIG. 9 as well. FIG. 10 is a diagram showing a light emitting device according to a tenth embodiment of the disclosure. As shown in FIG. 10, the support 710, the light emitting diode 120 and the material layer 930 of the light emitting device 1000 are identical to those shown in FIG. 9. Different from the embodiment of FIG. 9, the light emitting device 1000 of the disclosure does not comprise a phosphor layer. Oppositely, the light emitting device 1000 of the disclosure further comprises phosphor 150 distributed in the material layer 930, for converting the wavelength of light emitted from the light emitting diode 120. A primary size of the phosphor body 150 is between 5 micrometers and 30 micrometers. Similarly, the light emitting device 1000 can comprise at least two kinds of phosphor, which are distributed in the material layer 930, having different light emission peak wavelengths, such that the light emitted from the light emitting diode 120 can be converted into two different color light, so as to increase color saturation of the light emitting device 1000.

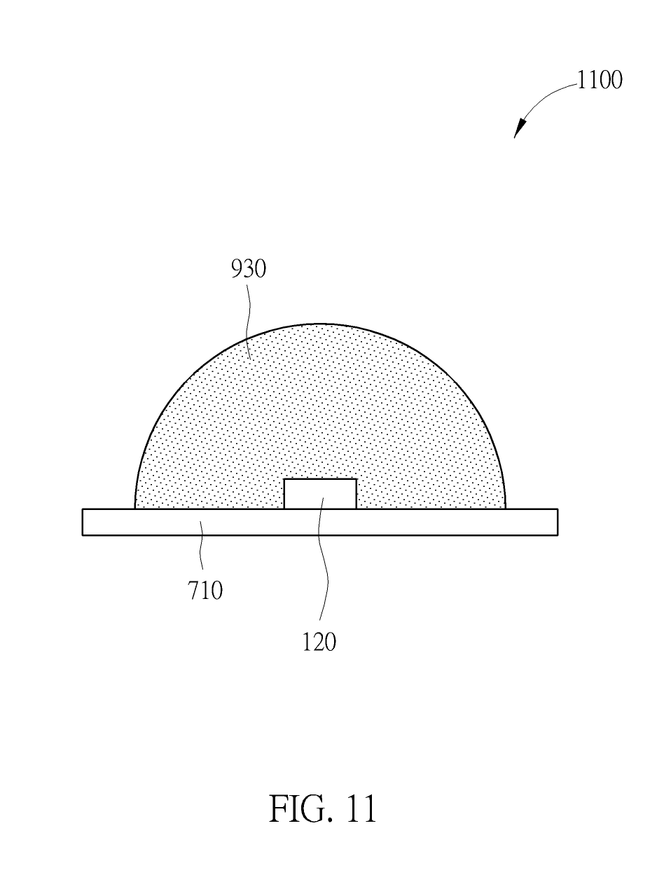

Please refer to FIG. 11, and refer to FIG. 9 as well. FIG. 11 is a diagram showing a light emitting device according to an eleventh embodiment of the disclosure. As shown in FIG. 11, the support 710, the light emitting diode 120 and the material layer 930 of the light emitting device 1100 are identical to those shown in FIG. 9. Different from the embodiment of FIG. 9, the light emitting device 1100 of the disclosure does not comprise a phosphor layer. The light emitting device 1100 of the disclosure can select a proper light emitting diode 120 according to design requirement, and utilize the light emitting diode 120 to directly emit light without wavelength conversion.

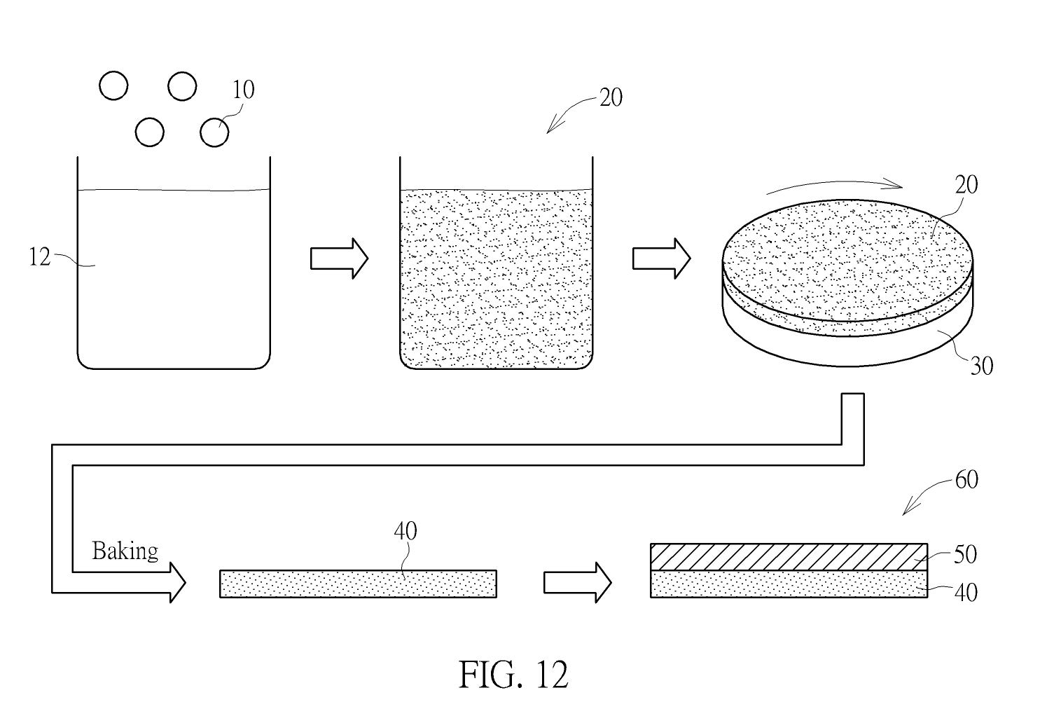

Please refer to FIG. 12. FIG. 12 is a diagram illustrating a manufacturing method for a wavelength conversion layer of the disclosure. As shown in FIG. 12, the disclosure dissolves particles or tablets of the poly(vinylidene fluoride-hexafluoropropylene) copolymer 10 in an organic solvent 12 to form a solution 20. The molecular weight of the poly(vinylidene fluoride-hexafluoropropylene) copolymer 10 can be but not limited to 400000 g/mole or 455000 g/mole. A weight percentage of the poly(vinylidene fluoride-hexafluoropropylene) copolymer 10 to the solution 20 is smaller than 15%. Thereafter, the solution 20 is uniformly applied on a substrate 30 by spin coating. After a baking process, the solution 20 applied on the substrate 30 forms a film type material layer 40, and the material layer 40 comprises the poly(vinylidene fluoride-hexafluoropropylene) copolymer. Finally, a phosphor layer 50 is formed on the material layer 40, such that a wavelength conversion layer 60 of the disclosure is obtained. The wavelength conversion layer 60 is applicable to the light emitting device of the disclosure (such as the light emitting device 400, 600 and 700), for converting the wavelength of light emitted from the light emitting diode.

On the other hand, in another manufacturing method for a wavelength conversion layer of the disclosure, the phosphor can be directly added in the organic solvent, for distributing the phosphor in the material layer formed by the poly(vinylidene fluoride-hexafluoropropylene) copolymer, so as to further form a wavelength conversion layer of the disclosure.

In the previous embodiment, the organic solvent 12 is acetone, this is because the poly(vinylidene fluoride-hexafluoropropylene) copolymer is easy to be dissolved in the acetone, but the disclosure is not limited to it. The organic solvent 12 can be other material.

In contrast to the prior art, the light emitting device of the disclosure utilizes the poly(vinylidene fluoride-hexafluoropropylene) copolymer to form a material layer in order to package a light emitting diode. Since the poly(vinylidene fluoride-hexafluoropropylene) copolymer is resistant to ultraviolet light and high temperature, the light emitting device of the disclosure can prevent yellowing aging phenomenon due to being exposed to ultraviolet radiation for a long time, and is applicable to package of high power light emitting diodes. The poly(vinylidene fluoride-hexafluoropropylene) copolymer can be arranged on the support in a filling or dispensing manner, or arranged on the light emitting diode as a film. The film type material layer can be flexible, thus the contact surface of the light emitting diode is not limited to a plane, the contact surface can also be a curved surface or other kind of irregular surfaces. In addition, the material layer is arranged between the phosphor layer and the light emitting diode, such that the light extraction can be improved, and heat exhaustion effect of the phosphor layer due to receiving heat directly can also be effectively prevented.

Those skilled in the art will readily observe that numerous modifications and alterations of the device and method may be made while retaining the teachings of the invention. Accordingly, the above disclosure should be construed as limited only by the metes and bounds of the appended claims.

What is claimed is:

1. A light emitting device, comprising:
a support;
a light emitting diode, arranged on the support, and coupled to the support, wherein a light emission peak wavelength of the light emitting diode is between 250 nm and 470 nm; and
a material layer, covering the light emitting diode, wherein the material layer comprises a poly(vinylidene fluoride-hexafluoropropylene) copolymer.

2. The light emitting device of claim 1, wherein the poly(vinylidene fluoride-hexafluoropropylene) copolymer is represented by a chemical formula: 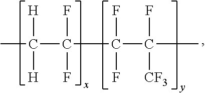
wherein a molecular weight of the poly(vinylidene fluoride-hexafluoropropylene) copolymer is between 390000 g/mole and 460000 g/mole, x and y are positive integers.

3. The light emitting device of claim 1, wherein the support has a recess, the light emitting diode is arranged in the recess, and the material layer is filled into the recess.

4. The light emitting device of claim 1, wherein the material layer comprises a film.

5. The light emitting device of claim 1 further comprising a phosphor layer arranged on the material layer.

6. The light emitting device of claim 1 further comprising phosphor distributed in the material layer.

7. The light emitting device of claim 2, wherein the molecular weight of the poly(vinylidene fluoride-hexafluoropropylene) copolymer is 400000 g/mole or 455000 g/mole.

8. A light emitting device, comprising:
a support;
an ultraviolet light emitting diode, arranged on the support, and coupled to the support; and
a material layer, covering the light emitting diode, wherein the material layer comprises a poly(vinylidene fluoride-hexafluoropropylene) copolymer.

9. The light emitting device of claim 8, wherein the poly(vinylidene fluoride-hexafluoropropylene) copolymer is represented by a chemical formula: 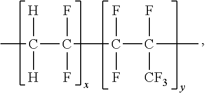
wherein a molecular weight of the poly(vinylidene fluoride-hexafluoropropylene) copolymer is between 390000 g/mole and 460000 g/mole, x and y are positive integers.

10. The light emitting device of claim 8, wherein the support has a recess, the light emitting diode is arranged in the recess, and the material layer is filled into the recess.

11. The light emitting device of claim 8, wherein the material layer comprises a film.

12. The light emitting device of claim 8 further comprising a phosphor layer arranged on the material layer.

13. The light emitting device of claim 8 further comprising phosphor distributed in the material layer.

14. The light emitting device of claim 8, wherein a light emission peak wavelength of the ultraviolet light emitting diode is 365 nm, 385 nm or 405 nm.

15. The light emitting device of claim 9, wherein the molecular weight of the poly(vinylidene fluoride-hexafluoropropylene) copolymer is 400000 g/mole or 455000 g/mole.

16. A light emitting device, comprising:
a support;
a light emitting diode, arranged on the support, and coupled to the support;
a material layer, covering the light emitting diode, wherein the material layer comprises a poly(vinylidene fluoride-hexafluoropropylene) copolymer; and
a phosphor layer, arranged on the light emitting diode for converting a wavelength of light emitted from the light emitting diode.

17. The light emitting device of claim 16, wherein the poly(vinylidene fluoride-hexafluoropropylene) copolymer is represented by a chemical formula: 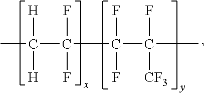
wherein a molecular weight of the poly(vinylidene fluoride-hexafluoropropylene) copolymer is between 390000 g/mole and 460000 g/mole, x and y are positive integers.

18. The light emitting device of claim 16, wherein the support has a recess, the light emitting diode is arranged in the recess, and the material layer is filled into the recess.

19. The light emitting device of claim 16, wherein the material layer comprises a film.

20. The light emitting device of claim 17, wherein the molecular weight of the poly(vinylidene fluoride-hexafluoropropylene) copolymer is 400000 g/mole or 455000 g/mole.
